(19) United States
(12) Patent Application Publication
(10) Pub. No.: US 2026/0090363 A1
(43) Pub. Date: Mar. 26, 2026

(54) SEMICONDUCTOR DIE SHIELDING STRUCTURE

(71) Applicant: Infineon Technologies Austria AG, Villach (AT)

(72) Inventor: Chuan CHEAH, Torrance, CA (US)

(21) Appl. No.: 18/894,558

(22) Filed: Sep. 24, 2024

(51) Int. Cl. H01L 23/528; H01L 21/768

(52) U.S. Cl. CPC H10W 20/435; H10W 20/056

(57) ABSTRACT

According to some embodiments, a device is provided that includes a pre-package and an interconnect package. The pre-package has a semiconductor die having a first contact pad, a molding layer over the semiconductor die, and a first contact comprising a first base portion embedded in the molding layer and contacting the first contact pad, and a first fan out portion over a portion of the molding layer and extending from the first base portion. The interconnect package has a first interconnect structure embedded in a dielectric material and contacting the first contact, wherein the pre-package is embedded in the dielectric material.

### BACKGROUND

Device packages perform various functions for semiconductor devices, including protection, interconnect routing, dielectric isolation between nodes, and providing external contact pads for interfacing with the semiconductor device. Techniques for forming device packages include molding processes and laminating processes.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

According to some embodiments, a device is provided that comprises a pre-package and an interconnect package. The pre-package comprises a semiconductor die comprising a first contact pad, a molding layer over the semiconductor die, and a first contact comprising a first base portion embedded in the molding layer and contacting the first contact pad, and a first fan out portion over a portion of the molding layer and extending from the first base portion. The interconnect package comprises a first interconnect structure embedded in a dielectric material and contacting the first contact, wherein the pre-package is embedded in the dielectric material.

According to some embodiments, a method is provided. The method comprises forming a molding layer over a semiconductor die, forming a first contact opening in the molding layer to expose a first contact pad of the semiconductor die, forming a conductive layer over the molding layer and in the first contact opening, patterning the conductive layer to form a first contact comprising a first base portion extending through the molding layer and contacting the first contact pad, and a first fan out portion extending from the first base portion over a first portion of the molding layer, mounting the semiconductor die in a recess of an interconnect package, forming a dielectric material in the recess, and forming a first interconnect structure embedded in the dielectric material and contacting the first contact.

According to some embodiments, a system is provided. The system comprises means for forming a molding layer over a semiconductor die, means for forming a first contact opening in the molding layer to expose a first contact pad of the semiconductor die, means for forming a conductive layer over the molding layer and in the first contact opening, means for patterning the conductive layer to form a first contact comprising a first base portion extending through the molding layer and contacting the first contact pad, and a first fan out portion extending from the first base portion over a first portion of the molding layer, means for mounting the semiconductor die in a recess of an interconnect package, means for forming a dielectric material in the recess, and means for forming a first interconnect structure embedded in the dielectric material and contacting the first contact.

According to some embodiments, a device is provided. The device comprises a semiconductor die comprising a power semiconductor device, comprising a first source/drain region, and a second source/drain region, a first contact pad connected to the first source/drain region, and a second contact pad connected to the second source/drain region, a molding layer over the semiconductor die, a first contact comprising a first base portion embedded in the molding layer and contacting the first contact pad, and a first fan out portion over a first portion of the molding layer and extending from the first base portion, a second contact comprising a second base portion embedded in the molding layer and contacting the second contact pad, and a second fan out portion over a second portion of the molding layer and extending from the second base portion, a first interconnect structure embedded in a dielectric material and contacting the first contact, and a second interconnect structure embedded in the dielectric material and contacting the second contact.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIGS. 1-7 are cross section diagrams of a device during various stages of manufacturing, in accordance with some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

It is to be understood that the following description of embodiments is not to be taken in a limiting sense. The scope of the present disclosure is not intended to be limited by the embodiments described hereinafter or by the drawings, which are taken to be illustrative only. The drawings are to be regarded as being schematic representations and elements illustrated in the drawings are not necessarily shown to scale. Rather, the various elements are represented such that their function and general purpose become apparent to a person skilled in the art.

All numerical values within the detailed description and the claims herein are modified by “about” or “approximately” the indicated value, and take into account experimental error and variations that would be expected by a person having ordinary skill in the art.

In some embodiments, a device comprises a semiconductor die in a pre-package embedded in an interconnect package. The pre-package comprises a molding layer over the semiconductor die and a contact embedded in the molding layer and contacting a contact pad of the semiconductor die. The contact comprises a base portion embedded in the molding layer and a fan out portion extending over a portion of the molding layer. The fan out portion maintains the spacing between the base portion of the contact and an edge of the semiconductor die and the molding layer helps reduce the likelihood of delamination of the layers formed over the semiconductor die.

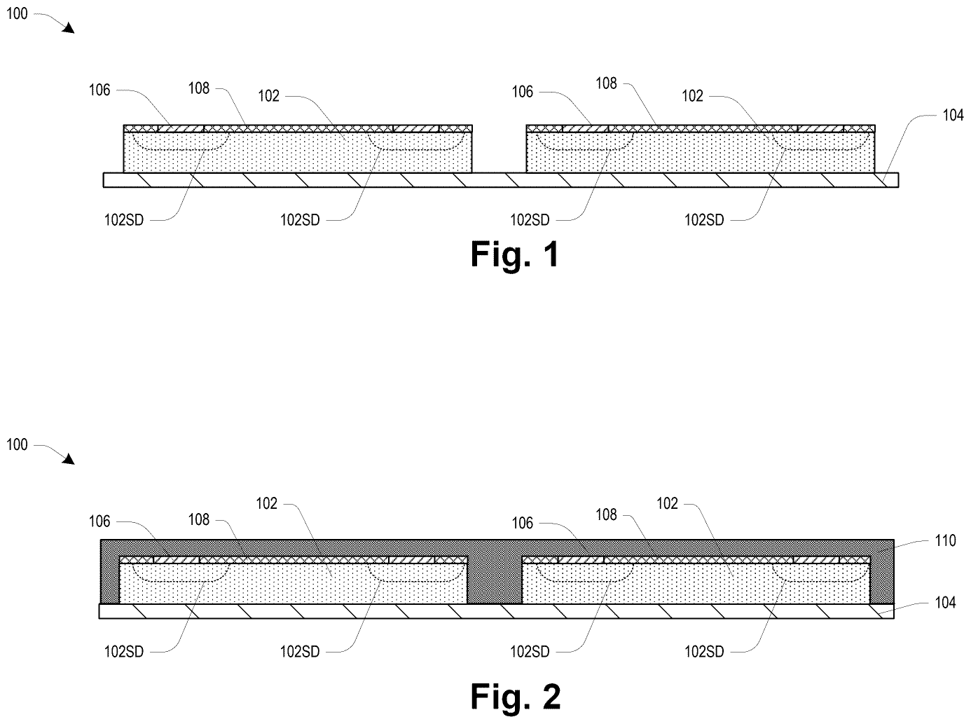

FIGS. 1-7 are cross-section views of a device 100 during various stages of manufacturing, in accordance with some embodiments. Referring to FIG. 1, the device 100 is assembled by mounting semiconductor dies 102 to a frame 104. The semiconductor die 102 comprise contact pads 106 extending through a passivation layer 108 (e.g., polyimide) to contact internal elements of the semiconductor die 102. In some embodiments, the semiconductor die 102 comprises a high voltage semiconductor device, such as a power transistor, and the contact pads 106 are source/drain contact pads that contact source/drain regions 102SD of the power transistor. The source/drain regions 102SD are stylistically illustrated using phantom lines and the illustration is not intended to show the actual structure of the power semiconductor device. The number of contact pads 106 may vary and other contact pads, for example a gate contact pad, may be provided in different positions along the axial lengths of the semiconductor die 102, such as into or out of the page. The semiconductor die 102 may be fabricated using a gallium nitride (GaN) fabrication process. A pick and place operation may be used to place the semiconductor dies 102.

Referring to FIG. 2, a molding layer 110 is formed over the semiconductor dies 102, in accordance with some embodiments. The molding layer 110 may be formed by a compression molding process using an epoxy molding compound.

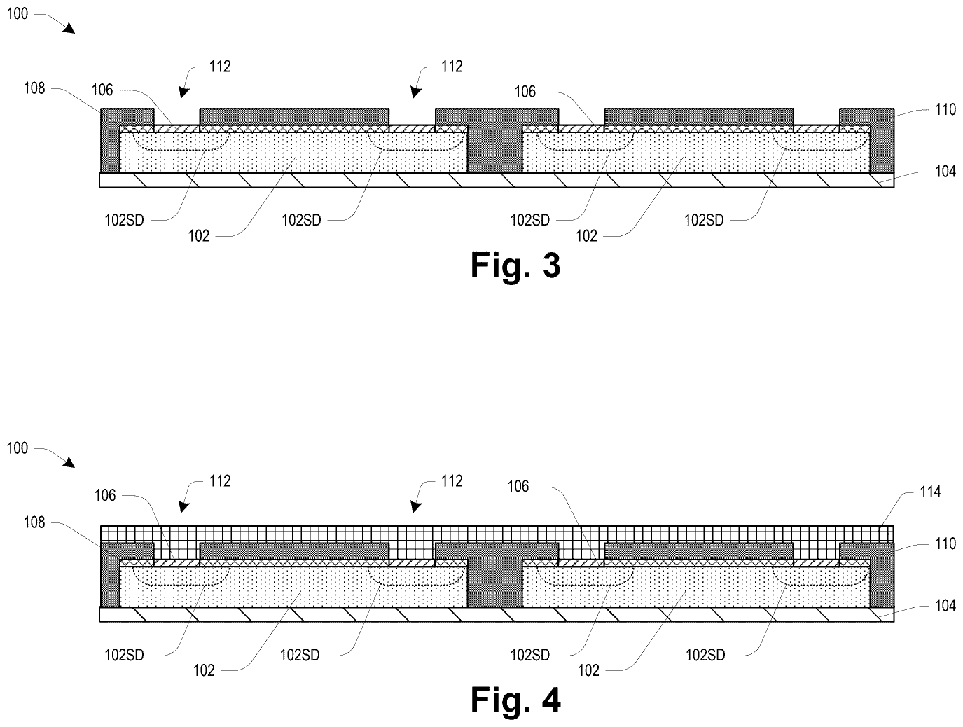

Referring to FIG. 3, contact openings 112 are formed in the molding layer 110 and the passivation layer 108 to expose the contact pads 106, in accordance with some embodiments. One or more lithography processes may be used to form the contact openings 112. An example lithography process includes an etch process using a patterned mask. The patterned mask may comprise a single layer, such as photoresist, or a plurality of individually formed layers that together form a mask stack. The photoresist may be a negative photoresist or a positive photoresist that is patterned to form openings above the portions of the molding layer 110 and the passivation layer 108 to be removed by the subsequent etch process.

Referring to FIG. 4, a conductive layer 114 is formed over the molding layer 110 and in the contact openings 112, in accordance with some embodiments. In some embodiments, the conductive layer 114 may comprises multiple layers, such as a barrier layer, a seed layer, a metal fill layer, or other suitable layers. Barrier materials may include one or more of titanium, titanium nitride, tantalum, tantalum nitride, cobalt or other suitable barrier materials. A seed material may include copper or other seed material. The metal fill layer may comprise copper, aluminum copper, tungsten, aluminum, copper, cobalt, or some other suitable material. In some embodiments, the contact pads 106 on the semiconductor die 102 may comprise copper, aluminum, tungsten, or some other suitable material.

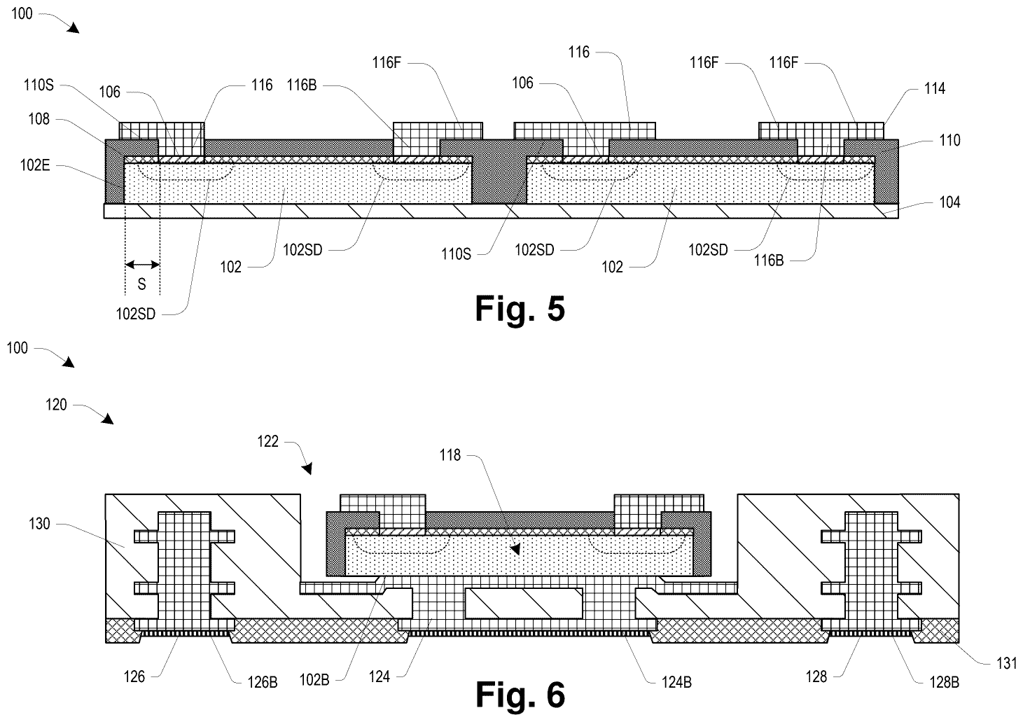

Referring to FIG. 5, the conductive layer 114 is patterned to form contacts 116 over the molding layer 110, in accordance with some embodiments. In some embodiments, thin film technology may be used to form the conductive layer 114 and the contacts 116. To form the conductive layer 114, a seed layer is applied first, typically by sputtering. The seed layer may include multiple layers, such as a barrier layer (e.g., Cr, Ti, Ta, TiW, or some other barrier material) of approximately 50 nm) and a plating layer (e.g., Cu with a thickness of approximately 150 nm). A plating resist is applied over the seed layer and is structured using photolithography. After development, the plating resist is opened at the positions where the conductive layer 114 is to be applied. Electro-plating may be used for adding material (e.g., Cu or metal stacks like CuNiAu) in the openings of the resist. The thickness of the electroplated layer may be 7 μm to 15 μm or even thicker. After metal plating (e.g., Cu/CuNiAu), the plating resist is removed and the seed layer is etched in two etching steps (Cu first, barrier layer second).

In some embodiments, the contacts 116 comprise a base portion 116B that extends through the molding layer 110 and the passivation layer 108 to contact the contact pads 106 and a fan-out portion 116F that extends over an upper surface 110S of the molding layer 110. The fan-out portion 116F may extend from the base portion 116B in direction, such as toward an edge 102E of the semiconductor die 102, as illustrated in the left semiconductor die 102, or fan-out portion 116F may extend in both directions from the base portion 116B, as illustrated in the right semiconductor die 102. The fan-out portion 116F increases the surface area of the contact 116, thereby reducing the resistance of the contact 116 while maintaining the standoff distance, S, of the base portion 116B from the edge 102E of the semiconductor die 102 to space the high voltage node defined by the contact 116 from the edge 102E. The edge spacing, S, may be about 3-5 μm. In some embodiments, molding layer 111 is about 5-7 μm thick, the base portions 116B are about 190-210 μm (e.g., 203 μm) wide, the fan out portions 116F can have various widths. The semiconductor die 102 and contacts 116 form a pre-package 118. Other structures and/or configurations of the contacts 116 are within the scope of the present disclosure.

Referring to FIG. 6, an individual pre-package 118 is removed from the frame 104 and embedded in an interconnect package 120, in accordance with some embodiments. The interconnect package 120 is fabricated with a recess 122 for receiving the semiconductor die 102. The interconnect package 120 comprises interconnect structures, such as base interconnect structures 124 and source/drain interconnect structures 126, 128, embedded in dielectric material 130 In some embodiments, the base interconnect structures 124 may contact a back surface 102B of the semiconductor die 102, which may be exposed substrate material or one more contact pads.

Back side contact pads 124B, 126B, 128B may be provided for the base interconnect structure 124 and the source/drain interconnect structures 126, 128, respectively. The back side contact pads 124B, 126B, 128B may be embedded in a backside passivation layer 131. In some embodiments, the dimensions of the semiconductor die 102 are approximately 2 mm×2 mm and the dimensions of the interconnect package 120 are approximately 8 mm×8 mm.

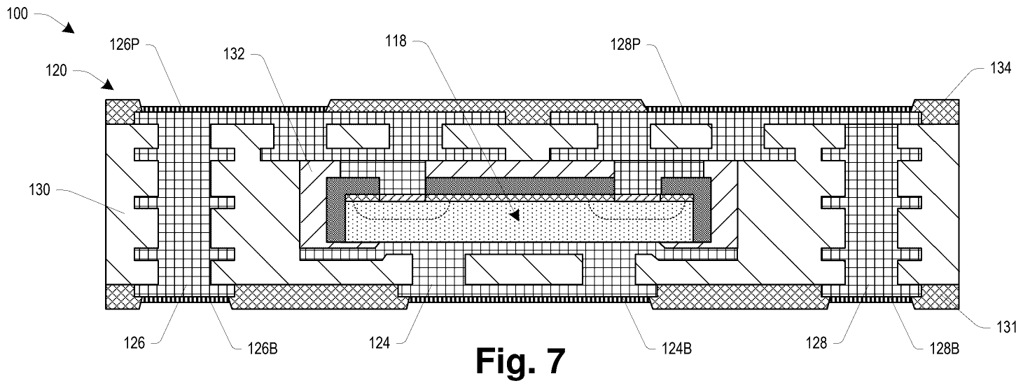

Referring to FIG. 7, a lamination process is performed to form a dielectric layer 132 in the recess 122 to encapsulate the semiconductor die 102 and to form additional metallization layers over the semiconductor die to further form the source/drain interconnect structures 126, 128 and to form front side contact pads 126P, 128P embedded in a frontside passivation layer 134. In some embodiments, the interconnect structures 124, 126, 128 comprise copper, and the contact pads 124B, 126B, 128B, 126P, 128P comprise ENEPIG stacks comprising electroless plated nickel (EN) electroless plated palladium (EP), and immersion plated gold (IG).

The base interconnect structures 124 may provide a path to dissipate substrate current and may also provide a heat sink for cooling the semiconductor die 102. The interconnect package 120 provides flexibility with both back side contact pads 124B, 126B, 128B and front side contact pads 124P, 126P, 128P.

The presence of the molding layer 110 over the passivation layer 108 and under the fan-out portion 116F of the contacts 116 on the semiconductor die 102 reduces the likelihood of delamination of layers formed after the semiconductor die 102 is embedded in the interconnect package 120.

According to some embodiments, a device is provided that comprises a pre-package and an interconnect package. The pre-package comprises a semiconductor die comprising a first contact pad, a molding layer over the semiconductor die, and a first contact comprising a first base portion embedded in the molding layer and contacting the first contact pad, and a first fan out portion over a portion of the molding layer and extending from the first base portion. The interconnect package comprises a first interconnect structure embedded in a dielectric material and contacting the first contact, wherein the pre-package is embedded in the dielectric material.

According to some embodiments, the first contact pad contacts a first source/drain region of a semiconductor device in the semiconductor die.

According to some embodiments, the pre-package comprises a second contact pad in the semiconductor die contacting a second source/drain region of the semiconductor device, and a second contact comprising a second base portion embedded in the molding layer and contacting the second contact pad, and a second fan out portion over a second portion of the molding layer and extending from the second base portion, and the interconnect package comprises a second interconnect structure embedded in the dielectric material and contacting the second contact.

According to some embodiments, the interconnect package comprises a second interconnect structure embedded in the dielectric material and contacting a substrate of the semiconductor die.

According to some embodiments, the interconnect package comprises a back side contact pad connected to the second interconnect structure.

According to some embodiments, the interconnect package comprises a front side contact pad connected to the first interconnect structure on a first surface of the interconnect package, and a back side contact pad connected to the first interconnect structure on a second surface of the interconnect package opposite the first surface.

According to some embodiments, the first fan out portion extends from the first base portion in a direction toward an edge of the semiconductor die.

According to some embodiments, the first fan out portion extends from the first base portion in a first direction toward an edge of the semiconductor die and in a second direction away from the edge of the semiconductor die.

According to some embodiments, a method is provided. The method comprises forming a molding layer over a semiconductor die, forming a first contact opening in the molding layer to expose a first contact pad of the semiconductor die, forming a conductive layer over the molding layer and in the first contact opening, patterning the conductive layer to form a first contact comprising a first base portion extending through the molding layer and contacting the first contact pad, and a first fan out portion extending from the first base portion over a first portion of the molding layer, mounting the semiconductor die in a recess of an interconnect package, forming a dielectric material in the recess, and forming a first interconnect structure embedded in the dielectric material and contacting the first contact.

According to some embodiments, the method comprises providing the first contact pad contacting a first source/drain region of a semiconductor device in the semiconductor die.

According to some embodiments, the method comprises forming a second contact opening in the molding layer to expose a second contact pad of the semiconductor die, wherein the second contact pad contacts a second source/drain region of the semiconductor device, forming the conductive layer comprises forming the conductive layer in the second contact opening, and patterning the conductive layer comprises patterning the conductive layer to form a second contact in the second contact opening comprising a second base portion extending through the molding layer and contacting the second contact pad, and a second fan out portion extending from the second base portion over a second portion of the molding layer, and forming a second interconnect structure embedded in the dielectric material and contacting the second contact.

According to some embodiments, mounting the semiconductor die in the recess comprises contacting a substrate of the semiconductor die to a second interconnect structure in the interconnect package, wherein the interconnect package comprises a back side contact pad connected to the second interconnect structure.

According to some embodiments, the method comprises providing the interconnect package comprising a front side contact pad connected to the first interconnect structure on a first surface of the interconnect package, and a back side contact pad connected to the first interconnect structure on a second surface of the interconnect package opposite the first surface.

According to some embodiments, patterning the conductive layer to form the first contact comprises forming the first fan out portion to extend from the first base portion in a direction toward an edge of the semiconductor die.

According to some embodiments, patterning the conductive layer to form the first contact comprises forming the first fan out portion to extend from the first base portion in a first direction toward an edge of the semiconductor die and in a second direction away from the edge of the semiconductor die.

According to some embodiments, a device is provided. The device comprises a semiconductor die comprising a power semiconductor device, comprising a first source/drain region, and a second source/drain region, a first contact pad connected to the first source/drain region, and a second contact pad connected to the second source/drain region, a molding layer over the semiconductor die, a first contact comprising a first base portion embedded in the molding layer and contacting the first contact pad, and a first fan out portion over a first portion of the molding layer and extending from the first base portion, a second contact comprising a second base portion embedded in the molding layer and contacting the second contact pad, and a second fan out portion over a second portion of the molding layer and extending from the second base portion, a first interconnect structure embedded in a dielectric material and contacting the first contact, and a second interconnect structure embedded in the dielectric material and contacting the second contact.

According to some embodiments, the device comprises a third interconnect structure embedded in the dielectric material and contacting a substrate of the semiconductor die.

According to some embodiments, the device comprises a back side contact pad connected to the third interconnect structure.

According to some embodiments, the device comprises a front side contact pad connected to the first interconnect structure on a first surface of the device, and a back side contact pad connected to the first interconnect structure on a second surface of the device opposite the first surface.

According to some embodiments, the first fan out portion extends from the first base portion in a first direction toward an edge of the semiconductor die and in a second direction away from the edge of the semiconductor die.

Various operations of embodiments are provided herein. The order in which some or all of the operations are described should not be construed as to imply that these operations are necessarily order dependent. Alternative ordering will be appreciated by one skilled in the art having the benefit of this description. Further, it will be understood that not all operations are necessarily present in each embodiment provided herein. Also, it will be understood that not all operations are necessary in some embodiments.

Any aspect or design described herein as an “example” is not necessarily to be construed as advantageous over other aspects or designs. Rather, use of the word “example” is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or more” unless specified otherwise or clear from context to be directed to a singular form. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

What is claimed is:

1. A device, comprising:
a pre-package comprising:
a semiconductor die comprising a first contact pad;
a molding layer over the semiconductor die; and
a first contact comprising:
a first base portion embedded in the molding layer and contacting the first contact pad; and
a first fan out portion over a portion of the molding layer and extending from the first base portion; and
an interconnect package, comprising:
a first interconnect structure embedded in a dielectric material and contacting the first contact, wherein:
the pre-package is embedded in the dielectric material.

2. The device of claim 1, wherein:
the first contact pad contacts a first source/drain region of a semiconductor device in the semiconductor die.

3. The device of claim 2, wherein:
the pre-package comprises:
a second contact pad in the semiconductor die contacting a second source/drain region of the semiconductor device; and
a second contact comprising:
a second base portion embedded in the molding layer and contacting the second contact pad; and
a second fan out portion over a second portion of the molding layer and extending from the second base portion; and
the interconnect package comprises:
a second interconnect structure embedded in the dielectric material and contacting the second contact.

4. The device of claim 1, wherein:
the interconnect package comprises:
a second interconnect structure embedded in the dielectric material and contacting a substrate of the semiconductor die.

5. The device of claim 4, wherein:
the interconnect package comprises:
a back side contact pad connected to the second interconnect structure.

6. The device of claim 1, wherein:
the interconnect package comprises:
a front side contact pad connected to the first interconnect structure on a first surface of the interconnect package; and
a back side contact pad connected to the first interconnect structure on a second surface of the interconnect package opposite the first surface.

7. The device of claim 1, wherein:
the first fan out portion extends from the first base portion in a direction toward an edge of the semiconductor die.

8. The device of claim 1, wherein:
the first fan out portion extends from the first base portion in a first direction toward an edge of the semiconductor die and in a second direction away from the edge of the semiconductor die.

9. A method, comprising:
forming a molding layer over a semiconductor die;
forming a first contact opening in the molding layer to expose a first contact pad of the semiconductor die;
forming a conductive layer over the molding layer and in the first contact opening;
patterning the conductive layer to form a first contact comprising:
a first base portion extending through the molding layer and contacting the first contact pad; and
a first fan out portion extending from the first base portion over a first portion of the molding layer;
mounting the semiconductor die in a recess of an interconnect package;
forming a dielectric material in the recess; and
forming a first interconnect structure embedded in the dielectric material and contacting the first contact.

10. The method of claim 9, comprising:
providing the first contact pad contacting a first source/drain region of a semiconductor device in the semiconductor die.

11. The method of claim 10, comprising:
forming a second contact opening in the molding layer to expose a second contact pad of the semiconductor die, wherein:
the second contact pad contacts a second source/drain region of the semiconductor device;
forming the conductive layer comprises forming the conductive layer in the second contact opening; and
patterning the conductive layer comprises patterning the conductive layer to form a second contact in the second contact opening comprising:
a second base portion extending through the molding layer and contacting the second contact pad; and
a second fan out portion extending from the second base portion over a second portion of the molding layer; and
forming a second interconnect structure embedded in the dielectric material and contacting the second contact.

12. The method of claim 9, wherein:
mounting the semiconductor die in the recess comprises:
contacting a substrate of the semiconductor die to a second interconnect structure in the interconnect package, wherein:
the interconnect package comprises:
a back side contact pad connected to the second interconnect structure.

13. The method of claim 9, comprising:
providing the interconnect package comprising:
a front side contact pad connected to the first interconnect structure on a first surface of the interconnect package; and
a back side contact pad connected to the first interconnect structure on a second surface of the interconnect package opposite the first surface.

14. The method of claim 9, wherein:
patterning the conductive layer to form the first contact comprises:
forming the first fan out portion to extend from the first base portion in a direction toward an edge of the semiconductor die.

15. The method of claim 9, wherein:
patterning the conductive layer to form the first contact comprises:
forming the first fan out portion to extend from the first base portion in a first direction toward an edge of the semiconductor die and in a second direction away from the edge of the semiconductor die.

16. A device, comprising:
a semiconductor die comprising:
a power semiconductor device, comprising:
a first source/drain region; and
a second source/drain region;
a first contact pad connected to the first source/drain region; and
a second contact pad connected to the second source/drain region;
a molding layer over the semiconductor die;
a first contact comprising:
a first base portion embedded in the molding layer and contacting the first contact pad; and
a first fan out portion over a first portion of the molding layer and extending from the first base portion;
a second contact comprising:
a second base portion embedded in the molding layer and contacting the second contact pad; and
a second fan out portion over a second portion of the molding layer and extending from the second base portion;
a first interconnect structure embedded in a dielectric material and contacting the first contact; and
a second interconnect structure embedded in the dielectric material and contacting the second contact.

17. The device of claim 16, comprising:
a third interconnect structure embedded in the dielectric material and contacting a substrate of the semiconductor die.

18. The device of claim 17, comprising:
a back side contact pad connected to the third interconnect structure.

19. The device of claim 16, comprising:
a front side contact pad connected to the first interconnect structure on a first surface of the device; and
a back side contact pad connected to the first interconnect structure on a second surface of the device opposite the first surface.

20. The device of claim 16, wherein:
the first fan out portion extends from the first base portion in a first direction toward an edge of the semiconductor die and in a second direction away from the edge of the semiconductor die.
